(19) United States
(12) Patent Application Publication
(10) Pub. No.: US 2025/0301622 A1
(43) Pub. Date: Sep. 25, 2025

(54) MEMORY CELL OF DYNAMIC RANDOM ACCESS MEMORY, ARRAY, MEMORY, AND DEVICE

(71) Applicants: Beijing Superstring Academy of Memory Technology, Beijing (CN); INSTITUTE OF MICROELECTRONICS, CHINESE ACADEMY OF SCIENCES, Beijing (CN)

(72) Inventors: Gaobo Xu, Beijing (CN); Jie Luo, Beijing (CN); Huaxiang Yin, Beijing (CN); Yanyu Yang, Beijing (CN); Gangping Yan, Beijing (CN); Chuqiao Niu, Beijing (CN); Yunjiao Bao, Beijing (CN)

(21) Appl. No.: 18/987,660

(22) Filed: Dec. 19, 2024

(30) Foreign Application Priority Data
Mar. 22, 2024 (CN) 202410339056.3

(51) Int. Cl. H10B 12/00

(52) U.S. Cl. CPC H10B 12/00

(57) ABSTRACT

A memory cell of a dynamic random access memory, an array, a memory, and a device are provided. The memory cell includes a write word line, a write bit line, a write transistor, a read word line, a read bit line and a read transistor. The read transistor includes multiple channel layers composed of different materials. A gate electrode, a first electrode and a second electrode of the write transistor are connected to the write word line, the write bit line and a gate electrode of the read transistor respectively. The first and second electrodes of the write transistor are respectively source and drain electrodes of the write transistor. First and second electrodes of the read transistor are connected to the read bit line and the read word line respectively. The first and second electrodes of the read transistor are respectively source and drain electrodes of the read transistor.

### CROSS REFERENCE TO RELATED APPLICATION

This application claims priority to Chinese Patent Application No. 202410339056.3, filed on Mar. 22, 2024, the entire content of which is incorporated herein in its entirety by reference.

### TECHNICAL FIELD

The present disclosure relates to a field of memory technology, and in particular to a memory cell of a dynamic random access memory, a storage array, a memory, and an electronic device.

### BACKGROUND

Dynamic random access memory (DRAM) is a semiconductor memory of which a main working principle is to represent a binary bit as 1 or 0 by using an amount of charges stored in a capacitor.

In the related art, dynamic random access memory DRAM cell made of IGZO (indium gallium zinc oxide) material is commonly used, in which a gate electrode of a read transistor is used as a storage node. The DRAM cell made of IGZO material has a technical problem that it is difficult to achieve multi-bit information storage through a single storage node.

The above contents are merely used to provide background information related to the present disclosure and do not necessarily constitute the related art.

### SUMMARY

An objective of the present disclosure is to provide a memory cell of a dynamic random access memory as well as a memory. A simplified summary is given below in order to provide a basic understanding of some aspects of the disclosed embodiments. The summary is not a general overview, nor is it intended to identify key/critical constituent elements or to delineate the scope of protection of the embodiments. Its sole objective is to present some concepts in a simplified form as a prelude to the detailed explanation to be described later.

According to an aspect of the embodiments of the present disclosure, a memory cell of a dynamic random access memory is provided, including a write word line, a write bit line, a write transistor, a read word line, a read bit line and a read transistor, where the read transistor includes a plurality of channel layers, and respective materials of the plurality of channel layers are different from each other;
a gate electrode of the write transistor is connected to the write word line, a first electrode of the write transistor is connected to the write bit line, a second electrode of the write transistor is connected to a gate electrode of the read transistor, the first electrode of the write transistor is one of a source electrode and a drain electrode of the write transistor, and the second electrode of the write transistor is the other of the source electrode and the drain electrode of the write transistor; and
a first electrode of the read transistor is connected to the read bit line, a second electrode of the read transistor is connected to the read word line, the first electrode of the read transistor is one of a source electrode and a drain electrode of the read transistor, and the second electrode of the read transistor is the other of the source electrode and the drain electrode of the read transistor.

In some embodiments of the present disclosure, each of the plurality of channel layers is made of an amorphous indium zinc oxide material, an amorphous indium gallium zinc oxide material, an amorphous tungsten oxide material, or an amorphous indium tin oxide material.

In some embodiments of the present disclosure, the read transistor includes the source electrode, the drain electrode, a bottom gate, a bottom gate insulating layer covering the bottom gate, and the plurality of channel layers stacked in sequence from bottom to top with the bottom gate insulating layer as a bottom layer, and each of the source electrode of the read transistor and the drain electrode of the read transistor is in contact with a topmost channel layer in the plurality of channel layers; and the gate electrode of the read transistor includes the bottom gate, and the second electrode of the write transistor is connected to the bottom gate of the read transistor.

In some embodiments of the present disclosure, the read transistor includes the source electrode, the drain electrode, a bottom gate, a bottom gate insulating layer, the plurality of channel layers, a top gate insulating layer and a top gate, the bottom gate insulating layer covers the bottom gate, the plurality of channel layers are stacked in sequence from bottom to top with the bottom gate insulating layer as a bottom layer, and each of the source electrode of the read transistor and the drain electrode of the read transistor is in contact with a topmost channel layer in the plurality of channel layers; the gate electrode of the read transistor includes the top gate and the bottom gate, and the second electrode of the write transistor is connected to the bottom gate of the read transistor; the read transistor is covered with an insulating protection layer, and the insulating protection layer is provided with an opening exposing a portion of the top gate; and each of the source electrode of the read transistor and the drain electrode of the read transistor penetrates the insulating protection layer and is in contact with the topmost channel layer in the plurality of channel layers.

In some embodiments of the present disclosure, the insulating protection layer is made of aluminum oxide or silicon dioxide.

In some embodiments of the present disclosure, the read transistor further includes a glass substrate layer, and the bottom gate is located on the glass substrate layer.

In some embodiments of the present disclosure, the top gate is made of molybdenum, the bottom gate is made of molybdenum, the source electrode is made of molybdenum, the drain electrode is made of molybdenum, the top gate insulating layer is made of silicon dioxide, and the bottom gate insulating layer is made of silicon dioxide.

According to another aspect of the embodiments of the present disclosure, a storage array is provided, including a plurality of memory cells of the dynamic random access memory as described in any embodiment of the present disclosure.

According to another aspect of the embodiments of the present disclosure, a memory is provided, including the storage array as described in any embodiment of the present disclosure.

According to another aspect of the embodiments of the present disclosure, an electronic device is provided, including the memory as described in any embodiment of the present disclosure.

The above description is merely an overview of the technical solutions of the embodiments of the present disclosure. In order to have a clearer understanding of the technical means of the embodiments of the present disclosure, it may be implemented in accordance with the contents of the specification. In order to make the above and other objectives, features and advantages of the embodiments of the present disclosure more obvious and easy to understand, specific implementations of the present disclosure will be described below.

### BRIEF DESCRIPTION OF THE DRAWINGS

In order to more clearly illustrate the embodiments of the present disclosure or the technical solutions in the related art, the accompanying drawings required for use in the embodiments or the description of the related art will be briefly introduced below. Obviously, the accompanying drawings described below are merely some embodiments recorded in the present disclosure. Those ordinary skilled in the art may obtain additional accompanying drawings according to these accompanying drawings without carrying out any inventive effort.

FIG. 1 shows a schematic structural diagram of a memory cell of a dynamic random access memory in an embodiment of the present disclosure.

FIG. 2 shows a carrier movement region when a gate voltage is a low voltage in an embodiment of the present disclosure.

FIG. 3 shows a carrier movement region when a gate voltage is a high voltage in an embodiment of the present disclosure.

FIG. 4 shows a relationship curve of a carrier mobility and a gate voltage in an embodiment of the present disclosure.

FIG. 5 shows a schematic structural diagram of a read transistor in an embodiment of the present disclosure.

FIG. 6 shows a schematic structural diagram of a read transistor in another embodiment of the present disclosure.

### DETAILED DESCRIPTION OF EMBODIMENTS

In order to make objectives, technical solutions and advantages of the present disclosure clearer, the present disclosure will be further described with reference to the accompanying drawings and specific embodiments. It should be understood that the specific embodiments described herein are merely used to explain the present disclosure and are not used to limit the present disclosure. Based on the embodiments of the present disclosure, all additional embodiments obtained by those ordinary skilled in the art without carrying out inventive effort fall within the scope of protection of the present disclosure.

Those skilled in the art may understand that, unless otherwise defined, all terms (including technical and scientific terms) used herein have the same meaning as generally understood by those ordinary skilled in the art to which the present disclosure pertains. It should also be understood that terms such as those defined in general dictionaries should be understood to have meanings consistent with those in the context of the related art and will not be interpreted with idealized or overly formal meanings unless specifically defined as herein.

In view of the technical problem in the related art that it is difficult for a DRAM cell made of IGZO material to achieve multi-bit information storage through a single storage node, an embodiment of the present disclosure provides a memory cell of a dynamic random access memory. The memory cell includes a write word line, a write bit line, a write transistor, a read word line, a read bit line and a read transistor, where the read transistor includes a plurality of channel layers, and respective materials of the plurality of channel layers are different from each other; a gate electrode of the write transistor is connected to the write word line, a first electrode of the write transistor is connected to the write bit line, a second electrode of the write transistor is connected to a gate electrode of the read transistor, the first electrode of the write transistor is one of a source electrode and a drain electrode of the write transistor, and the second electrode of the write transistor is the other of the source electrode and the drain electrode of the write transistor; and a first electrode of the read transistor is connected to the read bit line, a second electrode of the read transistor is connected to the read word line, the first electrode of the read transistor is one of a source electrode and a drain electrode of the read transistor, and the second electrode of the read transistor is the other of the source electrode and the drain electrode of the read transistor. The read transistor includes a plurality of channel layers, and respective materials of the plurality of channel layers are different from each other. The read transistor may form different current ranges under different voltage ranges, so that multi-bit information storage of a single storage node may be achieved, which solves the technical problem in the related art that it is difficult for the DRAM cell made of IGZO material to achieve multi-bit information storage through a single storage node.

The memory cell of the dynamic random access memory provided according to an embodiment of the present disclosure will be described below with reference to the accompanying drawings.

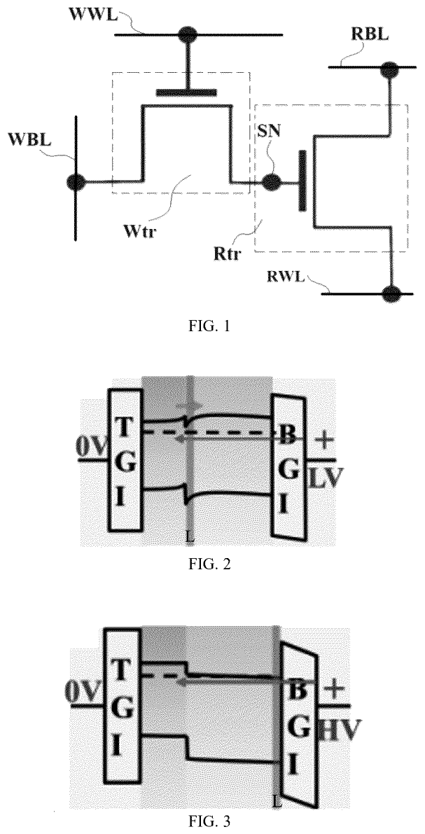

Referring to FIG. 1, an embodiment of the present disclosure provides a memory cell of a dynamic random access memory, including a write word line WWL, a write bit line WBL, a write transistor Wtr, a read word line RWL, a read bit line RBL and a read transistor Rtr. The read transistor Rtr includes a plurality of channel layers, and respective materials of the plurality of channel layers are different from each other. A channel layer refers to a region for current transmission in a transistor. By applying different voltages to the gate electrode of the transistor, it is possible to control a degree of conductivity in a portion composed of the plurality of channel layers, thereby achieving current regulation and switching operations.

The plurality of channel layers in the read transistor Rtr may include two, three or four channel layers, etc., and the plurality of channel layers may be stacked in sequence from bottom to top.

A gate electrode of the write transistor Wtr is connected to the write word line WWL, a first electrode of the write transistor Wtr is connected to the write bit line WBL, and a second electrode of the write transistor Wtr is connected to a gate electrode of the read transistor Rtr. The first electrode of the write transistor Wtr is one of a source electrode and a drain electrode of the write transistor Wtr, and the second electrode of the write transistor Wtr is the other of the source electrode and the drain electrode of the write transistor Wtr. For example, the first electrode of the write transistor Wtr is the source electrode of the write transistor Wtr, and the second electrode of the write transistor Wtr is the drain electrode of the write transistor Wtr. Alternatively, the first electrode of the write transistor Wtr is the drain electrode of the write transistor Wtr, and the second electrode of the write transistor Wtr is the source electrode of the write transistor Wtr.

A first electrode of the read transistor Rtr is connected to the read bit line RBL, and a second electrode of the read transistor Rtr is connected to the read word line RWL. The first electrode of the read transistor Rtr is one of a source electrode and a drain electrode of the read transistor Rtr, and the second electrode of the read transistor Rtr is the other of the source electrode and the drain electrode of the read transistor Rtr. For example, the first electrode of the read transistor Rtr is the source electrode of the read transistor Rtr, and the second electrode of the read transistor Rtr is the drain electrode of the read transistor Rtr. Alternatively, the first electrode of the read transistor Rtr is the drain electrode of the read transistor Rtr, and the second electrode of the read transistor Rtr is the source electrode of the read transistor Rtr.

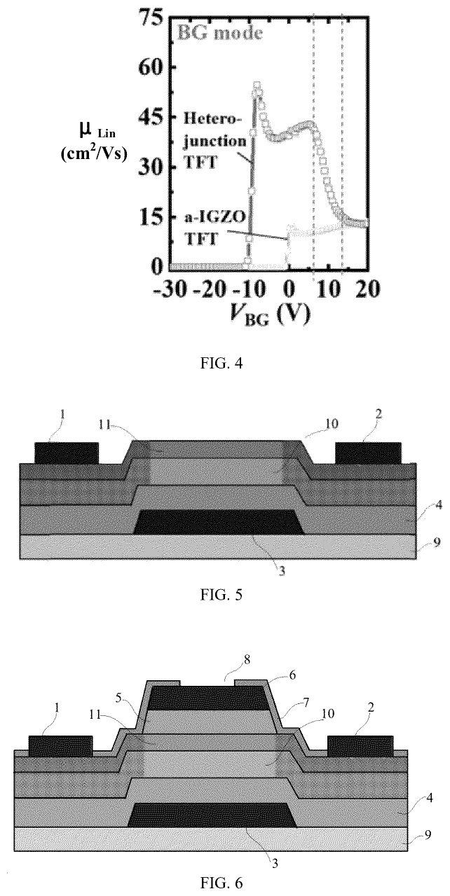

The plurality of channel layers in the read transistor Rtr may be stacked in sequence from bottom to top. The gate electrode of the read transistor Rtr may be used as a storage node (SN for short). The read transistor Rtr is a transistor with a plurality of channel layers, which has different channel mobility under different gate voltages. The channel mobility refers to a speed at which carriers move in the channel. Under different gate voltages, the current passes through different regions in the read transistor Rtr, and the carriers have different mobility, which leads to different current magnitudes. FIG. 2 shows a carrier movement region L when the gate voltage is a low voltage, and FIG. 3 shows a carrier movement region L when the gate voltage is a high voltage. For a device with a plurality of channel layers, the region that the current passes through is related to a band structure of a channel material and the gate voltage. Referring to FIG. 4, under different gate voltages, the current passes through different regions, and the carriers have different mobility, resulting in different current magnitudes. Different current magnitudes may correspond to different storage information, so that multi-bit information storage of a single storage node may be achieved.

A relationship between a gate voltage range, a read current range and a storage information in an example is shown in the table below.

| Gate voltage range | Read current range | Storage information |
|---|---|---|
| a | x | 1 |
| b | y | 2 |
| . . . | . . . | . . . |
| abc | xyz | n |

As shown in the table, all gate voltage ranges respectively correspond to all read current ranges, and all read current ranges respectively correspond to all storage information, so that multi-bit information storage of a single storage node may be achieved.

The write word line WWL, the write bit line WBL and the write transistor Wtr are used to write information to the storage node (i.e., the gate electrode of the read transistor Rtr) and store charges at the storage node, so that the gate electrode of the read transistor Rtr obtains a voltage. The read word line RWL, the read bit line RBL and the read transistor Rtr are used to read data at the storage node. The write transistor Wtr is a transistor used to write information to the storage node (i.e., the gate electrode of the read transistor Rtr). The read transistor Rtr is a transistor used to read data at the storage node. Since respective materials of the plurality of channel layers in the read transistor Rtr are different from each other, it is possible to form different current ranges under different voltage ranges. By detecting current states of the read transistor Rtr under different threshold voltages, it is possible to achieve multi-bit information storage of a single storage node.

Specifically, each of the plurality of channel layers is made of an amorphous indium zinc oxide material, an amorphous indium gallium zinc oxide material, an amorphous tungsten oxide material, or an amorphous indium tin oxide material.

Exemplarily, referring to FIG. 5, the read transistor Rtr includes a source electrode 1, a drain electrode 2, a bottom gate 3, a bottom gate insulating layer 4 covering the bottom gate 3, and the plurality of channel layers stacked in sequence from bottom to top with the bottom gate insulating layer 4 as a bottom layer. The source electrode 1 and the drain electrode 2 of the read transistor Rtr are both in contact with a topmost channel layer in the plurality of channel layers. The source electrode 1 and the drain electrode 2 of the read transistor Rtr are located at both sides of the bottom gate 3 respectively. The gate electrode of the read transistor Rtr is the bottom gate 3, and the second electrode of the write transistor Wtr is connected to the bottom gate 3 of the read transistor Rtr. The bottom gate 3 of the read transistor Rtr serves as a storage node. By using the bottom gate 3 as a storage node, it is possible to achieve a small size, a high density, a high integration and a great reading and writing speed, so as to achieve a memory cell with good performance. The read transistor Rtr shown in FIG. 5 has two channel layers, including a channel layer 10 and a channel layer 11 on the channel layer 10. The channel layer 10 is made of an amorphous indium gallium zinc oxide material, and the channel layer 11 is made of an amorphous indium zinc oxide material.

Exemplarily, referring to FIG. 6, the read transistor Rtr includes a source electrode 1, a drain electrode 2, a bottom gate 3, a bottom gate insulating layer 4, the plurality of channel layers, a top gate insulating layer 5, and a top gate 6. The bottom gate insulating layer 4 covers the bottom gate 3. The plurality of channel layers are stacked in sequence from bottom to top with the bottom gate insulating layer 4 as a bottom layer. The source electrode 1 and the drain electrode 2 of the read transistor Rtr are both in contact with a topmost channel layer in the plurality of channel layers. The source electrode 1 and the drain electrode 2 of the read transistor Rtr are located at both sides of the top gate 6 respectively. The gate electrode of the read transistor Rtr includes the top gate 6 and the bottom gate 3, and the second electrode of the write transistor Wtr is connected to the bottom gate 3 of the read transistor Rtr. The bottom gate 3 of the read transistor Rtr serves as a storage node. By using the bottom gate 3 as a storage node, it is possible to achieve a small size, a high density, a high integration and a great reading and writing speed, so as to achieve a memory cell with good performance.

In an optional embodiment, the read transistor Rtr is covered with an insulating protection layer 7, and the insulating protection layer 7 is provided with an opening 8 that exposes a portion of the top gate 6. An exposed portion of the top gate 6 may be connected to an external wire. The source electrode 1 and the drain electrode 2 of the read transistor Rtr both penetrate the insulating protection layer 7 and are in contact with a topmost channel layer in the plurality of channel layers. The insulating protection layer 7 may protect the read transistor Rtr to prevent a portion covered by the insulating protection layer 7 from being damaged by external forces.

Optionally, the insulating protection layer 7 may be made of aluminum oxide or silicon dioxide.

In some embodiments, the read transistor Rtr further includes a glass substrate layer 9, and the bottom gate 3 of the read transistor Rtr is located on the glass substrate layer 9. The glass substrate layer 9 provides a stable mechanical support for the read transistor Rtr to ensure a structural stability and reliability of the transistor during operation. The glass substrate layer has good insulation performance and may effectively prevent current leakage.

Specifically, in the read transistor Rtr, the top gate 6 is made of molybdenum, the bottom gate 3 is made of molybdenum, the source electrode 1 is made of molybdenum, the drain electrode 2 is made of molybdenum, the top gate insulating layer 5 is made of silicon dioxide, and the bottom gate insulating layer 4 is made of silicon dioxide.

In the example shown in FIG. 6, the read transistor Rtr has two channel layers, including a channel layer 10 and a channel layer 11 on the channel layer 10. The channel layer 10 is made of an amorphous indium gallium zinc oxide material, and the channel layer 11 is made of an amorphous indium zinc oxide material.

In another example, the read transistor Rtr has three channel layers stacked in sequence from bottom to top, and the three channel layers are made of different materials. Each of the three channel layers may be made of an amorphous indium zinc oxide material, an amorphous indium gallium zinc oxide material, an amorphous tungsten oxide material, or an amorphous indium tin oxide material.

In another example, the read transistor Rtr has four channel layers stacked in sequence from bottom to top, which are respectively made of an amorphous indium zinc oxide material, an amorphous indium gallium zinc oxide material, an amorphous tungsten oxide material and an amorphous indium tin oxide material.

The memory cell in the embodiments of the present disclosure may be a 2T0C multi-bit DRAM memory cell, which has a read transistor with a plurality of channel layers so that different channel carrier mobility may be provided under different voltage ranges at the storage node, thereby forming different current ranges.

In the related art, when a single DRAM memory cell made of IGZO material stores data, the read transistor Rtr is allowed to operate in a linear region to distinguish different storage information according to different current magnitudes corresponding to different voltages. However, a current value in the linear region is small (generally at nA or pA level), and it is difficult for a peripheral circuit to detect a too small current; the memory cell has a too small capacitance, resulting in a fast leakage of stored charges and a high refresh frequency; and an available voltage range in the linear region is small, resulting in a small discrimination of multi-bit storage. In contrast, for the memory cell of the dynamic random access memory in the embodiments of the present disclosure, a current value in the linear region is large, which facilitates a peripheral circuit detection; the storage node has a large capacitance, resulting in a slow leakage of stored charges and a low refresh frequency; and the available voltage range in the linear region is large, resulting in a large discrimination of multi-bit storage, thereby achieving a better beneficial technical effect compared with the related art.

The above description of various embodiments tends to emphasize differences between various embodiments. The same or similar parts may be referenced to each other and will not be repeated herein for the sake of simplicity.

Another embodiment of the present disclosure provides a storage array including a plurality of memory cells, and the memory cell is the memory cell of the dynamic random access memory in any embodiment of the present disclosure.

The storage array is a device designed specifically to provide high-capacity and high-performance data storage and access. The storage array combines a plurality of memory cells together to provide a greater total capacity and a higher data processing performance. The storage array may provide data protection and redundancy through different data redundancy technologies (such as RAID) to prevent data loss.

The storage array is widely used in enterprise-level data centers, cloud computing environments, large-scale databases, virtualization platforms, and other scenarios that require high-performance and high-reliability data storage and access.

Another embodiment of the present disclosure provides a memory, including the storage array in any embodiment of the present disclosure. The memory may include, for example, an internal memory, a solid-state disk, a storage server, a network storage device, or a virtualized storage system, etc.

Another embodiment of the present disclosure provides an electronic device, including the memory in any embodiment of the present disclosure. The electronic device may include, for example, a computer, a smart phone, or a tablet computer.

The technical solutions provided in an aspect of the embodiments of the present disclosure may have the following beneficial effects:

The memory cell of the dynamic random access memory provided by the embodiments of the present disclosure includes a write word line, a write bit line, a write transistor, a read word line, a read bit line and a read transistor, where the read transistor includes a plurality of channel layers, and respective materials of the plurality of channel layers are different from each other; a gate electrode of the write transistor is connected to the write word line, a first electrode of the write transistor is connected to the write bit line, a second electrode of the write transistor is connected to a gate electrode of the read transistor, the first electrode of the write transistor is one of a source electrode and a drain electrode of the write transistor, and the second electrode of the write transistor is the other of the source electrode and the drain electrode of the write transistor; and a first electrode of the read transistor is connected to the read bit line, a second electrode of the read transistor is connected to the read word line, the first electrode of the read transistor is one of a source electrode and a drain electrode of the read transistor, and the second electrode of the read transistor is the other of the source electrode and the drain electrode of the read transistor. The read transistor includes a plurality of channel layers, and respective materials of the plurality of channel layers are different from each other. The read transistor may form different current ranges under different voltage ranges, so that multi-bit information storage of a single storage node may be achieved.

It should be noted that the above embodiments merely express implementations of the present disclosure with specific and detailed descriptions, but the above should not be construed as limiting the scope of protection of the present disclosure. It should be noted that those ordinary skilled in the art may make some modifications and improvements without departing from the concept of the present disclosure, which all fall within the scope of protection of the present disclosure. The scope of protection of the present disclosure should be defined by the appended claims.

What is claimed is:

1. A memory cell of a dynamic random access memory, comprising: a write word line, a write bit line, a write transistor, a read word line, a read bit line and a read transistor, wherein the read transistor comprises a plurality of channel layers, and respective materials of the plurality of channel layers are different from each other;
wherein a gate electrode of the write transistor is connected to the write word line, a first electrode of the write transistor is connected to the write bit line, a second electrode of the write transistor is connected to a gate electrode of the read transistor, the first electrode of the write transistor is one of a source electrode and a drain electrode of the write transistor, and the second electrode of the write transistor is the other of the source electrode and the drain electrode of the write transistor; and
wherein a first electrode of the read transistor is connected to the read bit line, a second electrode of the read transistor is connected to the read word line, the first electrode of the read transistor is one of a source electrode and a drain electrode of the read transistor, and the second electrode of the read transistor is the other of the source electrode and the drain electrode of the read transistor.

2. The memory cell according to claim 1, wherein each of the plurality of channel layers is made of an amorphous indium zinc oxide material, an amorphous indium gallium zinc oxide material, an amorphous tungsten oxide material, or an amorphous indium tin oxide material.

3. The memory cell according to claim 1, wherein the read transistor comprises the source electrode, the drain electrode, a bottom gate, a bottom gate insulating layer covering the bottom gate, and the plurality of channel layers stacked in sequence from bottom to top with the bottom gate insulating layer as a bottom layer, and each of the source electrode of the read transistor and the drain electrode of the read transistor is in contact with a topmost channel layer in the plurality of channel layers; and
wherein the gate electrode of the read transistor comprises the bottom gate, and the second electrode of the write transistor is connected to the bottom gate of the read transistor.

4. The memory cell according to claim 2, wherein the read transistor comprises the source electrode, the drain electrode, a bottom gate, a bottom gate insulating layer covering the bottom gate, and the plurality of channel layers stacked in sequence from bottom to top with the bottom gate insulating layer as a bottom layer, and each of the source electrode of the read transistor and the drain electrode of the read transistor is in contact with a topmost channel layer in the plurality of channel layers; and wherein the gate electrode of the read transistor comprises the bottom gate, and the second electrode of the write transistor is connected to the bottom gate of the read transistor.

5. The memory cell according to claim 1, wherein the read transistor comprises the source electrode, the drain electrode, a bottom gate, a bottom gate insulating layer, the plurality of channel layers, a top gate insulating layer and a top gate, the bottom gate insulating layer covers the bottom gate, the plurality of channel layers are stacked in sequence from bottom to top with the bottom gate insulating layer as a bottom layer, and each of the source electrode of the read transistor and the drain electrode of the read transistor is in contact with a topmost channel layer in the plurality of channel layers;
wherein the gate electrode of the read transistor comprises the top gate and the bottom gate, and the second electrode of the write transistor is connected to the bottom gate of the read transistor;
wherein the read transistor is covered with an insulating protection layer, and the insulating protection layer is provided with an opening exposing a portion of the top gate; and
wherein each of the source electrode of the read transistor and the drain electrode of the read transistor penetrates the insulating protection layer and is in contact with the topmost channel layer in the plurality of channel layers.

6. The memory cell according to claim 2, wherein the read transistor comprises the source electrode, the drain electrode, a bottom gate, a bottom gate insulating layer, the plurality of channel layers, a top gate insulating layer and a top gate, the bottom gate insulating layer covers the bottom gate, the plurality of channel layers are stacked in sequence from bottom to top with the bottom gate insulating layer as a bottom layer, and each of the source electrode of the read transistor and the drain electrode of the read transistor is in contact with a topmost channel layer in the plurality of channel layers;
wherein the gate electrode of the read transistor comprises the top gate and the bottom gate, and the second electrode of the write transistor is connected to the bottom gate of the read transistor;
wherein the read transistor is covered with an insulating protection layer, and the insulating protection layer is provided with an opening exposing a portion of the top gate; and wherein each of the source electrode of the read transistor and the drain electrode of the read transistor penetrates the insulating protection layer and is in contact with the topmost channel layer in the plurality of channel layers.

7. The memory cell according to claim 5, wherein the insulating protection layer is made of aluminum oxide or silicon dioxide.

8. The memory cell according to claim 5, wherein the read transistor further comprises a glass substrate layer, and the bottom gate is located on the glass substrate layer.

9. The memory cell according to claim 5, wherein the top gate is made of molybdenum, the bottom gate is made of molybdenum, the source electrode is made of molybdenum, the drain electrode is made of molybdenum, the top gate insulating layer is made of silicon dioxide, and the bottom gate insulating layer is made of silicon dioxide.

10. A storage array, comprising a plurality of memory cells of the dynamic random access memory according to claim 1.

11. A memory, comprising the storage array according to claim 10.

12. An electronic device, comprising the memory according to claim 11.
